(19) United States
(12) Patent Application Publication
(10) Pub. No.: US 2024/0131655 A1
(43) Pub. Date: Apr. 25, 2024

(54) CHEMICAL MECHANICAL POLISHING DEVICE AND POLISHING METHOD

(71) Applicant: Powerchip Semiconductor Manufacturing Corporation, Hsinchu (TW)

(72) Inventors: Ming-Hsiang Chen, Taichung City (TW); Shih-Ci Yen, Hsinchu County (TW); Kai-Yao Shih, Hsinchu City (TW)

(73) Assignee: Powerchip Semiconductor Manufacturing Corporation, Hsinchu (TW)

(21) Appl. No.: 17/994,411

(22) Filed: Nov. 28, 2022

(30) Foreign Application Priority Data
Oct. 18, 2022 (TW) 111139585

(51) Int. Cl. B24B 37/32; B24B 37/04

(52) U.S. Cl. CPC B24B 37/32; B24B 37/042

(57) ABSTRACT

The present disclosure provides a chemical mechanical polishing device including a retaining ring and a wafer carrier and a polishing method. The retaining ring is configured on a polishing pad and includes an inner sidewall defining an opening and an outer sidewall opposite to the inner sidewall. The wafer carrier is configured on the polishing pad and is capable of placing a wafer disposed thereon into the opening and facing the polishing pad. The retaining ring has a notch at the corner adjacent to the wafer and the polishing pad.

### CROSS-REFERENCE TO RELATED APPLICATION

This application claims the priority benefit of Taiwan application serial no. 111139585, filed on Oct. 19, 2022. The entirety of the above-mentioned patent application is hereby incorporated by reference herein and made a part of this specification.

### BACKGROUND OF THE INVENTION

### 1. Field of the Invention

The invention relates to a chemical mechanical polishing device and a polishing method.

### 2. Description of Related Art

In the manufacturing process of components in the industry, the polishing process is a technique commonly used to planarize the surface of the object to be polished. In the polishing process, the surface of the object is gradually flattened by relative movement between the object and the polishing pad, so as to achieve the purpose of planarization. In addition, it is also an option to add a polishing slurry with a chemical mixture on the polishing pad during the polishing process, so that the surface of the object can be planarized under the co-effect of the mechanical effect and chemical effect. For example, a chemical mechanical polishing (CMP) process is one of the polishing methods that adds the polishing slurry with the chemical mixture on the polishing pad during the polishing process.

However, when the object and the retaining ring are both pressed on the polishing pad, a protrusion of the polishing pad is formed at the edge of the object due to the deformation of the polishing pad caused by the pressure pressed thereon. As such, the polishing profile of the object at the edges is difficult to control.

### SUMMARY OF THE INVENTION

The present invention provides a chemical mechanical polishing device and a polishing method in which the retaining ring is designed to have a notch at a corner adjacent to the wafer and the polishing pad, so that a protrusion of the polishing pad which is formed at the edge of the wafer due to the deformation of the polishing pad caused by the pressure pressed thereon (e.g., the pressure that the retaining ring being pressed on the polishing pad) can be located in the notch, and thus the polishing profile of the wafer at the edge can be well controlled.

An embodiment of the invention provides a chemical mechanical polishing device comprising a retaining ring and a wafer carrier. The retaining ring is configured on the polishing pad and includes an inner sidewall defining an opening and an outer sidewall opposite to the inner sidewall. The wafer carrier is configured on the polishing pad and is capable of placing a wafer disposed thereon into the opening and facing the polishing pad and. The retaining ring has a notch at a corner adjacent to the wafer and the polishing pad.

In some embodiments, the notch is a continuous ring shape notch.

In some embodiments, a surface of the notch spaces apart from the wafer by a distance, and the distance decreases gradually in a direction away from the polishing pad.

In some embodiments, the notch includes a first edge adjacent to the polishing pad and a second edge opposite to the first edge. The first edge spaces apart from the wafer by a distance being about 2 mm to about 5 mm.

In some embodiments, the second edge has a height respective to a level of the first edge, and the height is greater than the thickness of the wafer.

In some embodiments, a surface of the notch includes a curved surface.

In some embodiments, the inner sidewall includes a first profile defined by the notch and a second profile different from the first profile.

In some embodiments, the first profile is a curved profile, and the second profile is a planar profile.

An embodiment of the invention provides a polishing method suitable for polishing an object. The polishing method includes the following steps. The above chemical mechanical polishing device is provided. A first pressure is applied to the retaining ring to press the retaining ring onto the polishing pad. A second pressure is applied to the wafer carrier to press the wafer carried thereon onto the polishing pad. A relative motion between the wafer and the polishing pad is applied.

In some embodiments, when the first pressure and the second pressure are applied to the retaining ring and the wafer carrier, respectively, a protrusion of the polishing pad formed at the edge of the wafer due to the deformation is located in the notch.

Based on the above, in the aforementioned chemical mechanical polishing device and the polishing method, the retaining ring is designed to have a notch at a corner adjacent to the wafer and the polishing pad, so that a protrusion of the polishing pad formed at the edge of the wafer due to the deformation of the polishing pad caused by the pressure pressed thereon (e.g., the pressure that the retaining ring being pressed on the polishing pad) can be located in the notch, and thus the polishing profile of the wafer at the edge can be well controlled.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-section view illustrating a chemical mechanical polishing device of an embodiment of the invention.

FIG. 2 is a perspective view illustrating the retaining ring of FIG. 1.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

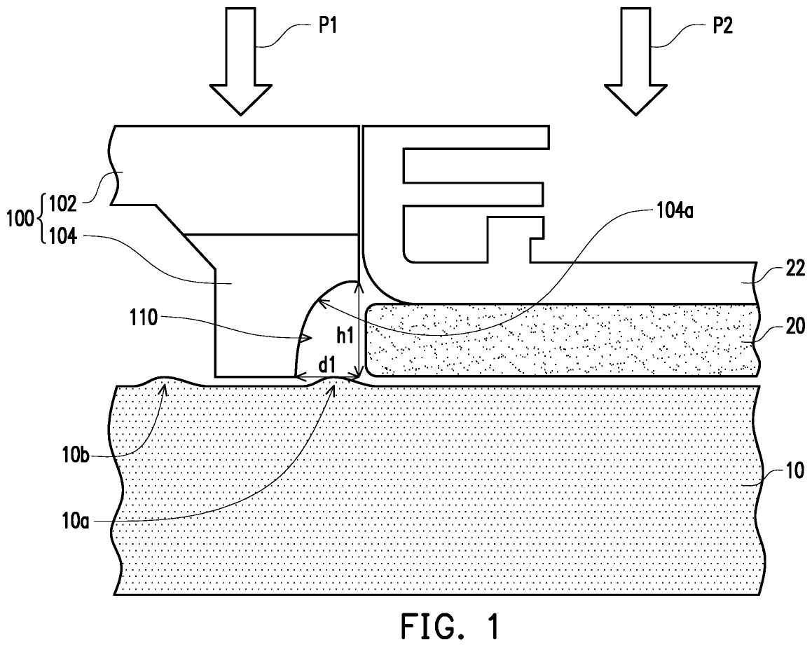

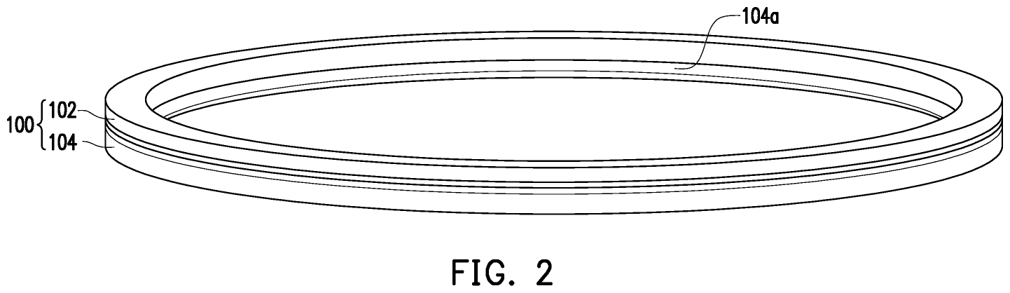

FIG. 1 is a schematic cross-section view illustrating a chemical mechanical polishing device of an embodiment of the invention. FIG. 2 is a perspective view illustrating the retaining ring of FIG. 1.

Referring to FIG. 1 and FIG. 2, a chemical mechanical polishing device includes a retaining ring 100 and a wafer carrier 22. The retaining ring 100 is configured on the polishing pad 10 and includes an inner sidewall defining an opening and an outer sidewall opposite to the inner sidewall (as shown in FIG. 2). The wafer carrier 22 is disposed on the polishing pad 10 and is capable of placing a wafer 20 into the opening and making the wafer 20 face the polishing pad 10. The retaining ring 100 has a notch 110 at a corner adjacent to the wafer 20 and the polishing pad 10. As such, a protrusion (e.g., protrusion 10a) of the polishing pad 10 formed at the edge of the wafer 20 due to the deformation of the polishing pad 10 caused by the pressure pressed thereon can be located in the notch 110, and thus the polishing profile of the wafer 20 at the edge can be well controlled. In some embodiments, the notch 110 is a continuous ring shape notch (as shown in FIG. 2).

In some embodiments, a surface 104a of the notch 110 spaces apart from the wafer 20 by a distance, and the distance may decrease gradually in a direction (e.g., a direction being perpendicular to the polishing pad 10) away from the polishing pad 10.

In some embodiments, the notch 110 may include a first edge (e.g., an edge near the polishing pad 10) adjacent to the polishing pad and a second edge (e.g., an edge away from the polishing pad 10) opposite to the first edge. The first edge spaces apart from the wafer 20 by a distance dl, and the distance dl is about 2 mm to about 5 mm. In the case where the distance dl is less than 2 mm, it may be hard for the notch 110 to accommodate the protrusion (e.g., protrusion 10a) of the polishing pad 10 formed at the edge of the wafer 20 due to the deformation of the polishing pad 10 caused by the pressure pressed thereon. In the case where the distance dl is greater than 5 mm, the life time of the retaining ring 100 may be reduced.

In some embodiments, the second edge has a height h1 respective to a level of the first edge, and the height h1 may be greater than the thickness of the wafer 20. As such, the concern of the wafer 20 being broken due to the squeeze of the retaining ring 100 can be prevented, and the height h1 is enough to accommodate the protrusion (e.g., protrusion 10a) of the polishing pad 10 formed at the edge of the wafer 20 due to the deformation of the polishing pad 10 caused by the pressure pressed thereon, and thereby stabilizing the polishing rate of the polishing pad 10.

In some embodiments, the surface 104a of the notch 110 may include a curved surface. As such, the abrasives in the polishing slurry are not easily attached to and crystallized on the inner sidewall of the retaining ring 100. Even if the abrasives in the polishing slurry attach and crystallize on the inner sidewall of the retaining ring 100, the crystallizations attached on the surface of the notch 110 can be well removed by the cleaning liquid when performing the cleaning process on the retaining ring 100. As a result, the crystallizations will not fall off and remain on the polishing pad 10, and thus the defects such as micro-scratch caused by the crystallizations will not occur on the surface of the wafer being polished. In some embodiments, the inner sidewall of the retaining ring 100 includes a first profile defined by the notch 110 and a second profile different from the first profile. For example, as shown in FIG. 1, the inner sidewall of the retaining ring 100 includes a curved profile (i.e., the first profile of the surface 104a) and a planar profile (i.e., the second profile) over the notch 110.

In some embodiments, a planarization process may be performed on the wafer according to the following polishing method. Firstly, as shown in FIG. 1, the chemical mechanical polishing device is provided, wherein the wafer 20 may be fixed on the wafer carrier 22 and disposed in the opening defined by the inner sidewall of the retaining ring 100 to avoid sliding. Next, a first pressure P1 is applied on the retaining ring 100 to press the retaining ring 100 onto the polishing pad 10, and a second pressure P2 is applied on the wafer carrier 22 to press the wafer 20 carried thereon onto the polishing pad 10. Then, a relative motion is applied between the wafer and the polishing pad. When the first pressure P1 and the second pressure P2 are applied to the retaining ring 100 and the wafer carrier 22, respectively, the polishing pad 10 is deformed and generates protrusions 10a and 10b on the polishing surface. The protrusion 10a formed at the edge of the wafer 20 can be accommodated in the notch 110, so that the deformation does not affect the planarization degree of the polishing pad 10 at the edge of the wafer 20, which is benefit to the control of the polishing profile of the wafer 20 at the edge.

In some embodiments, the first pressure P1 may be different from the second pressure P2. In some alternative embodiments, the first pressure P1 may be equal to or larger than the second pressure P2.

In some embodiments, the retaining ring 100 may include a first portion 102 and a second portion 104 adjacent to the polishing pad 10 and under the first portion 102. In some embodiments, the notch 110 may be formed at the corner of the second portion 104 of the retaining ring 100 adjacent to the wafer 20 and the polishing pad 10.

In some embodiments, there is no interface where different materials in contact with each other between the first portion 102 and the second portion 104, that is, the first portion 102 and the second portion 104 are integrally formed to be in contact with each other, but the invention is not limited thereto. In some alternative embodiments, an interface where different materials in contact with each other may exist between the first portion 102 and the second portion 104.

In some embodiments, the polishing pad 10 may include a polymer base material. For example, the polymer base material may be polyester, polyether, polyurethane, polycarbonate, polyacrylate, polybutadiene, other polymer base materials formed by synthesizing a suitable thermosetting resin or thermoplastic resin, or a combination thereof.

Based on the above, in the forgoing chemical mechanical polishing device and the polishing method, the retaining ring is designed to have a notch at a corner adjacent to the wafer and the polishing pad, so that a protrusion of the polishing pad formed at the edge of the wafer due to the deformation of the polishing pad caused by the pressure pressed thereon (e.g., the pressure that the retaining ring being pressed on the polishing pad) can be located in the notch, and thus the polishing profile of the wafer at the edge can be well controlled.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A chemical mechanical polishing device, comprising:
a retaining ring configured on a polishing pad and comprising an inner sidewall defining an opening and an outer sidewall opposite to the inner sidewall; and
wafer carrier configured on the polishing pad and being capable of placing a wafer disposed thereon into the opening and facing the polishing pad,
wherein the retaining ring has a notch at a corner adjacent to the wafer and the polishing pad.

2. The chemical mechanical polishing device of claim 1, wherein the notch is a continuous ring shape notch.

3. The chemical mechanical polishing device of claim 1, wherein a surface of the notch spaces apart from the wafer by a distance, and the distance decreases gradually in a direction away from the polishing pad.

4. The chemical mechanical polishing device of claim 1, wherein the notch comprises a first edge adjacent to the polishing pad and a second edge opposite to the first edge, and the first edge spaces apart from the wafer by a distance being about 2 mm to about 5 mm.

5. The chemical mechanical polishing device of claim 4, wherein the second edge has a height respective to a level of the first edge, and the height is greater than the thickness of the wafer.

6. The chemical mechanical polishing device of claim 1, wherein a surface of the notch comprises a curved surface.

7. The chemical mechanical polishing device of claim 1, wherein the inner sidewall comprises a first profile defined by the notch and a second profile different from the first profile.

8. The chemical mechanical polishing device of claim 7, wherein the first profile is a curved profile, and the second profile is a planar profile.

9. A polishing method suitable for polishing an object, the polishing method comprising:
providing the chemical mechanical polishing device of claim 1;
applying a first pressure to the retaining ring to press the retaining ring onto the polishing pad;
applying a second pressure to the wafer carrier to press the wafer carried thereon onto the polishing pad; and
applying a relative motion between the wafer and the polishing pad.

10. The polishing method of claim 9, wherein when the first pressure and the second pressure are applied to the retaining ring and the wafer carrier, respectively, a protrusion of the polishing pad formed at the edge of the wafer due to the deformation is located in the notch.
